(19) United States
(12) Patent Application Publication
(10) Pub. No.: US 2012/0223335 A1
(43) Pub. Date: Sep. 6, 2012

(54) METHOD OF MARKING SiC SEMICONDUCTOR WAFER AND SiC SEMICONDUCTOR WAFER

(75) Inventor: Noriaki TSUCHIYA, Tokyo (JP)

(73) Assignee: MITSUBISHI ELECTRIC CORPORATION, Chiyoda-ku (JP)

(21) Appl. No.: 13/274,645

(22) Filed: Oct. 17, 2011

(30) Foreign Application Priority Data
Mar. 4, 2011 (JP) 2011-047205

(51) Int. Cl. H01L 29/161; B23K 26/00

(52) U.S. Cl. 257/77; 219/121.61; 257/E29.084

(57) ABSTRACT

Marking of an SiC wafer with an identifier is realized by irradiation with a pulsed laser using a harmonic of a wavelength four times that of a YAG laser. A speed at which a laser head moves, an orbit in which the laser head moves, the output power and Q-switch frequency of a pulsed laser to be applied, and the like are determined such that pulse-irradiated marks formed as a result of irradiation with corresponding pulses of the pulsed laser do not overlap each other.

### BACKGROUND OF THE INVENTION

1. Field of the Invention

The present invention relates to a technique of laser marking of a silicon carbide semiconductor wafer.

2. Description of the Background Art

A semiconductor element using silicon carbide (SiC) is regarded as a promising element to function as a next-generation switching element capable of realizing high breakdown voltage, low loss, and high resistance to heat, and is expected to be applied in a power semiconductor device such as an inverter.

In order to easily identify and manage semiconductor wafers to be produced in large quantities in the manufacture of a semiconductor device, marking is generally employed in which identifies are engraved on surfaces of the semiconductor wafers in an initial stage of the wafer processing. Marking techniques of a conventional silicon (Si) semiconductor wafer (hereinafter called “Si wafer”) for example include marking (laser marking) to form a recessed irradiation mark by irradiating the Si wafer with a laser, and marking to cut a surface of the Si wafer with a diamond cutter, and others.

A pulsed laser repeatedly turned on and off at certain intervals is used in the laser marking of the conventional Si wafer, and which forms an irradiation mark (pulse-irradiated mark) with application of one pulse that is a relatively large mark of a size range of from several tens to several hundreds of micrometers. In order to provide visibility, several pulse-irradiated marks are partially overlaid to form a continuous irradiation mark, and the irradiation mark is formed into a great depth by applying a laser of high output power.

A basic YAG laser (λ=1,064 nm) and a green laser (λ=532 nm) are mainly employed as lasers for the laser marking of the Si wafer. Marking with the basic YAG laser (λ=1,064 nm) is called “hard marking,” and which allows formation of an irradiation mark of high visibility while causing a high probability of generation of particles. Marking with the green laser (λ=532 nm) capable of making output power low for its high absorptance (for its low transmittance) is called “soft marking,” and which suppresses generation of particles while a resultant irradiation mark has lower visibility.

As described above, in the conventional laser marking, several pulse-irradiated marks are partially overlaid to form a continuous irradiation mark in order to enhance the visibility of the mark. However, overlapping the pulse-irradiated marks results in the formation of projections in the generation of splashes in the overlapping portion. More particles are generated if the projections are dispersed. So, the laser marking involves a trade-off between suppression of particles and provision of visibility.

Japanese Patent Application Laid-Open No. 2005-101305 discloses an example of use of a harmonic (λ=266 nm) of a wavelength four times that of a YAG laser during marking of an inorganic nitride material such as a gallium nitride substrate.

Management of particles in any environments such as those in a clean room, in a semiconductor manufacturing device and on a wafer is an important issue in semiconductor wafer processing. Many adverse effects such as secondary contamination inside the clean room and the manufacturing device, failure in the manufacturing process, and resultant characteristic degradation of a semiconductor device may be generated due to particles if the particles are not managed strictly. So, reducing the amount of particle generation and taking countermeasures against generated particles are important issues to be achieved in each manufacturing device.

Marking of a semiconductor wafer particularly generates particles in large quantities as it directly processes the semiconductor wafer with a laser and the like. The particles generated by the marking are collected in a marking unit, or removed in a step of processing the semiconductor wafer. However, particles left unremoved may generate the aforementioned problems.

An SiC semiconductor wafer (hereinafter called “SiC wafer”) has higher transmittance to laser than the conventional Si wafer. So, in order to provide the visibility of an irradiation mark, the SiC wafer requires laser irradiation at higher output power even if the SiC wafer is to be subjected to marking with a laser such as a green laser having a relatively short wavelength. This results for example in the breakage of the crystalline structure of SiC if the SiC wafer is subjected to the same marking technique as that applied for the conventional Si wafer, generating particles excessively.

### SUMMARY OF THE INVENTION

It is an object of the present invention to provide a method of marking capable of maintaining high visibility of an engraved pattern and capable of suppressing generation of particles during laser marking of an SiC wafer.

The method of marking of an SiC semiconductor wafer of the present invention includes steps (a) and (b). In the step (a), an SiC semiconductor wafer is prepared. In the step (b), a laser is applied from a laser head to the SiC semiconductor wafer while the laser head is caused to move relative to the SiC semiconductor wafer, thereby engraving a predetermined pattern on a surface of the SiC semiconductor wafer. The predetermined pattern has irradiation marks as a result of irradiation with the laser. The laser is a pulsed laser of a wavelength four times that of a YAG laser. In the step (b), the laser head moves at a speed that prevents overlap between irradiation marks by continuous pulses of the pulsed laser, and in an orbit that prevents one of the irradiation marks previously formed from being irradiated with the pulsed-laser again.

The pulsed laser using a harmonic of a wavelength four times that of a YAG laser, and which has a high absorptance (low transmittance) is applied to the SiC semiconductor wafer, allowing the output power of the pulsed laser to be made low. Further, irradiation marks formed as a result of irradiation with corresponding pulses do not overlap. So, the irradiation marks are given stable shapes (projections in the form of splashes are not generated), thereby suppressing generation of particles. The irradiation marks formed at low output power do not provide high visibility if they are viewed alone. However, the irradiation marks are placed densely as they are continuously formed by causing the laser head to move, so that the pattern as an aggregate of the irradiation marks is provided with visibility.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1A shows an exemplary structure of an SiC wafer of a preferred embodiment of the present invention;

FIG. 1B shows an exemplary identifier engraved on the SiC wafer;

FIG. 2 shows a relationship between a direction in which a laser head moves and pulse-irradiated marks of the preferred embodiment of the present invention;

FIG. 3 shows a dot in an enlarged manner that forms the identifier of the SiC wafer of the preferred embodiment of the present invention;

FIG. 4 shows a relationship between the output power of a pulsed laser and the depth of a pulse-irradiated marks;

FIG. 5 shows a relationship between a speed at which the laser head moves and a distance between pulse-irradiated marks; and

FIG. 6 shows a relationship between the Q-switch frequency of a pulsed laser, the depth of pulse-irradiated marks, and a distance between the pulse-irradiated marks.

### EMBODIMENT FOR CARRYING OUT THE INVENTION

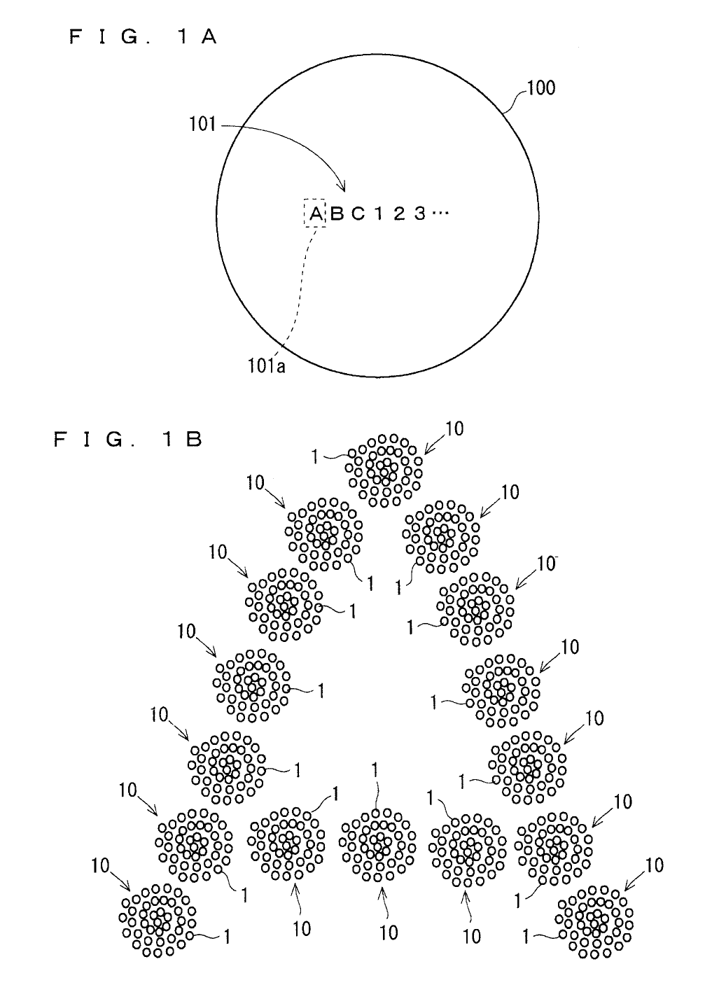

FIG. 1A shows an exemplary structure of an SiC wafer 100 of a preferred embodiment of the present invention. As shown in FIG. 1A, the pattern of an identifier 101 is engraved by laser marking on a surface of the SiC wafer 100. In the example shown here, the identifier 101 includes characters “ABC123 . . . .”

FIG. 1B shows a region 101a in an enlarged manner that includes the pattern of a character “A” of the identifier 101. The pattern of the identifier 101 is an aggregate of a plurality of dots 10 that do not overlap each other. As shown in the example of FIG. 1B, the character “A” is an aggregate of 16 dots 10. The dots 10 are formed by irradiation with a pulsed laser. Irradiation marks (pulse-irradiated marks) 1 in each of the dots 10 formed by irradiation with corresponding pulses of the pulsed laser do not overlap each other. That is, the dots 10 are each an aggregate of densely placed pulse-irradiated marks 1 separated from each other.

In the preferred embodiment, the pulse-irradiated marks 1 have a relatively small diameter of about 10 μm. The small pulse-irradiated marks 1 do not provide high visibility if they are viewed alone. However, the visibility of the dots 10 (namely, the visibility of the identifier 101) is provided as the pulse-irradiated marks 1 are placed densely to form the dots 10.

A method of marking the SiC wafer of the preferred embodiment is described below. The present invention employs a pulsed laser (UV laser) using a harmonic (λ=266 nm) of a wavelength four times that of a YAG laser, and which has a relatively high absorptance (low transmittance).

First, the SiC wafer 100 targeted for the marking is prepared, and the SiC wafer 100 is fixed to a marking unit capable of outputting a pulsed laser using an UV laser. Then, the pulsed laser of an UV laser is applied from a laser head of the marking unit to the SiC wafer 100 while the laser head is caused to move relative to the SiC wafer 100 while, thereby achieving marking to engrave the pattern of the identifier 101 with the pulse-irradiated marks 1 on a surface of the SiC wafer 100.

This marking step includes first and second marking steps. In the first marking step, a plurality of pulse-irradiated marks 1 not overlapping each other are formed to render one dot 10. In the second marking step, the pattern of the identifier 101 (such as the pattern of the character “A”) with a plurality of dots 10 is rendered by repeating the first marking step.

In order to form a dot 10 as an aggregate of separated pulse-irradiated marks 1 in the first marking step, a pulsed laser should be applied to a predetermined position of the SiC wafer 100 while the laser head is caused to move at a speed that prevents overlap between continuous pulse-irradiated marks 1, and in a manner that prevents a pulse-irradiated mark 1 previously formed from being irradiated with a laser again.

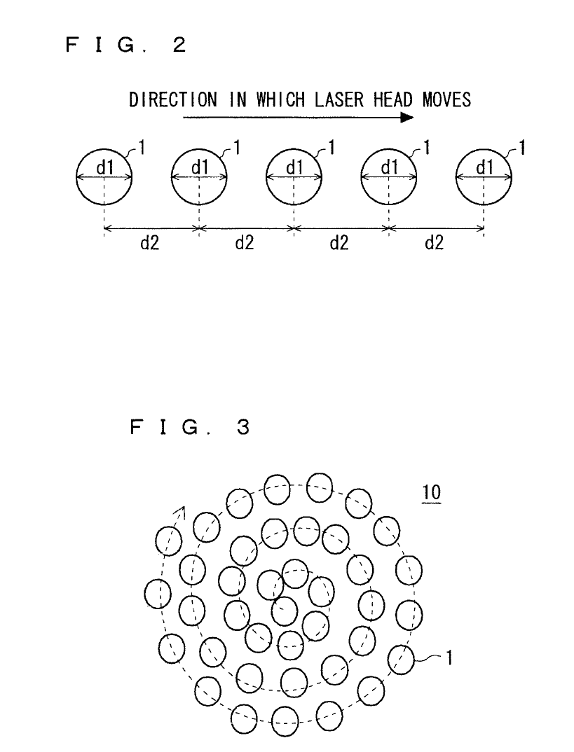

As described above, a pulsed laser is an intermittent laser repeatedly turned on and off. The preferred embodiment makes a cessation period (pulse interval) be sufficiently longer than a period of laser irradiation (pulse width). As a result, the laser head moves a distance longer than the diameter of a pulse-irradiated mark in the cessation period to prevent overlap between continuous pulse-irradiated marks if the laser head moves at a speed (laser head speed) higher than a certain speed. To be specific, separated pulse-irradiated marks 1 are aligned in a direction in which the laser head moves as shown in FIG. 2. A length d1 of FIG. 2 is the diameter of the pulse-irradiated marks 1, and a length d2 of FIG. 2 is a distance between the centers of continuous pulse-irradiated marks 1.

Making the laser head move in an orbit that does not pass through the same place more than once is the easiest way in the first marking step in order to prevent a pulse-irradiated mark 1 previously formed from being irradiated with a laser again. FIG. 3 shows the dot 10 in an enlarged manner. In the preferred embodiment, the dot 10 is rendered by causing the laser head to move in a spiral orbit (dashed line with an arrow head). The spiral orbit does not pass through the same place more than once, thereby preventing a pulse-irradiated mark 1 previously formed from being irradiated with a laser again.

Various parameters (irradiation parameters) relating to irradiation with a pulsed laser are established in preparation for the first marking step. The irradiation parameters include for example output power [W], laser head speed [mm/s], and Q-switch (Q-SW) frequency [Hz]. These irradiation parameters are described below.

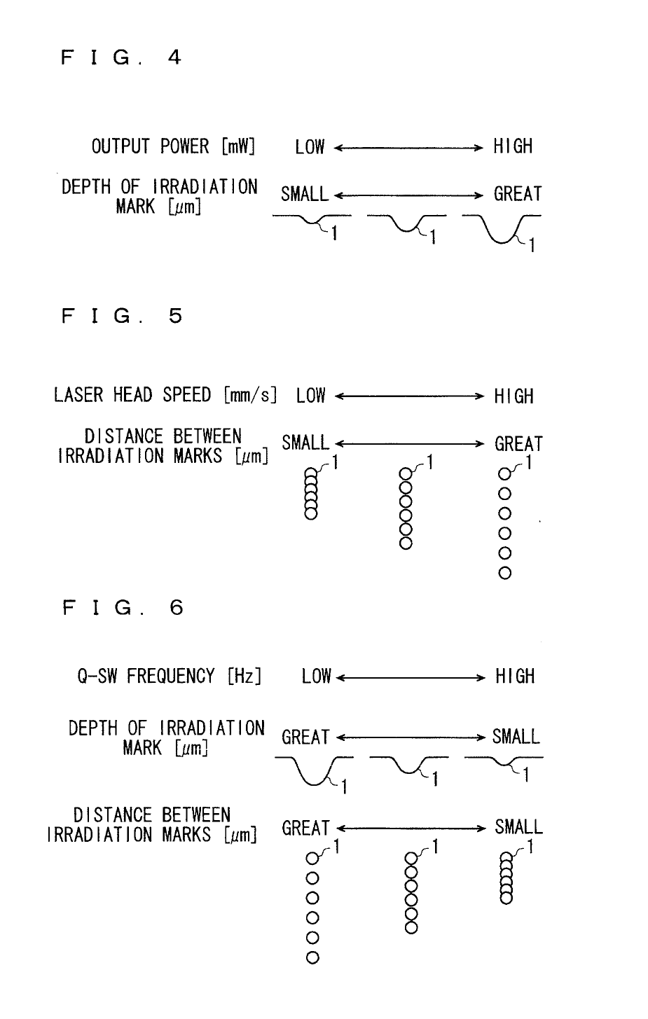

The output power is a parameter corresponding to the irradiation intensity of a pulsed laser, and which contributes to the depth of the pulse-irradiated marks 1 to be formed. FIG. 4 shows a relationship between the output power of a pulsed laser and the depth of the pulse-irradiated marks 1. The energy of one pulse (pulse energy) [J] becomes greater if the output power of a pulsed laser is increased while the Q-switch frequency is kept at a constant level, making the pulse-irradiated marks 1 to be formed into a greater depth. The dots 10 are given enhanced visibility if the pulse-irradiated marks 1 are formed into a greater depth. This however generates particles easily during formation of the pulse-irradiated marks 1.

The speed at which the laser head moves (laser head speed) is a parameter contributing to the distance between pulse-irradiated marks 1 formed continuously. FIG. 5 shows a relationship between the laser head speed and a distance between the pulse-irradiated marks 1. The distance between the pulse-irradiated marks 1 is increased if the laser head speed is made higher while the Q-switch frequency is kept at a constant level. Making the distance between the pulse-irradiated marks 1 prevents overlap between the pulse-irradiated marks 1 to suppress generation of particles. However, the visibility of the dots 10 is lowered if the pulse-irradiated marks 1 are placed sparsely by setting the distance between the pulse-irradiated marks 1 too large.

The Q-switch frequency is a parameter contributing to the pulse period [s] of a pulsed-laser and the energy of one pulse (pulse energy) [J]. FIG. 6 shows a relationship between the Q-switch frequency of a pulsed laser, the depth of the pulse-irradiated marks 1, and a distance between the pulse-irradiated marks 1. The pulse period of the pulsed laser is made longer and the energy of one pulse is made greater if the Q-switch frequency is lowered while the output power and the laser head speed are kept at their constant levels, resulting in the increase of the depth of the pulse-irradiated marks 1 and in the increase of the distance between the pulse-irradiated marks 1. Conversely, the pulse period of the pulsed laser is made shorter and the energy of one pulse is made smaller if the Q-switch frequency is increased, resulting in the reduction of the depth of the pulse-irradiated marks 1 and in the reduction of the distance between the pulse-irradiated marks 1.

The following relationship is established between the output power of a pulsed laser [W/s], the Q-switch frequency [Hz], and the pulse energy [J]:

(pulse energy)=(output power)/(Q-switch frequency) (1)

As described above, in the preferred embodiment, the identifier 101 engraved on the SiC wafer 100 is an aggregate of separated pulse-irradiated marks 1 (more specifically, the dots 10 forming the identifier 101 are each an aggregate of the pulse-irradiated marks 1). The pulse-irradiated marks 1 each have a stable shape as the pulse-irradiated marks 1 do not overlap each other (projections in the form of splashes are not generated), thereby suppressing generation of particles.

The high absorptance (low transmittance) of an UV laser (λ=266 nm) used as a pulsed laser for marking controls an output power at a low level. This also provides the stable shape of pulse-irradiated marks to suppress generation of particles.

The pulse-irradiated marks 1 of the preferred embodiment have a relatively small size of about 10 μm. A laser requires high output power for formation of a conventional large pulse-irradiated mark, resulting in unstable shape of the pulse-irradiated mark. In contrast, the small pulse-irradiated marks 1 can be formed with a laser having low output power, so that generation of particles is suppressed more effectively. The small pulse-irradiated marks 1 provide poor visibility if they are viewed alone. However, the dots 10 each including the densely placed pulse-irradiated marks 1, and the identifier 101 as an aggregate of the dots 10 are formed into patterns with sufficient visibility.

Thus, the preferred embodiment reduces the probability of generation, dispersion, stay, dripping and the like of particles while providing the visibility of the identifier 101 formed on the SiC wafer 100, so that subsequent processes are protected from the effect of contamination due to particles.

The irradiation parameters established in the first marking step may not be constant parameters but may be changed where necessary. As an example, increasing a distance between pulse-irradiated marks 1 lowers the visibility of the dots 10. However, increase of the distance between pulse-irradiated marks 1 also advantageously reduces the amount of particle generation to increase a throughput. There is a trade-off between visibility required for the identifier 101, and the amount of particle generation and a throughput. So, suitably controlling each of the irradiation parameters in consideration of this trade-off relationship makes it possible to effectively apply a laser in response to an object of marking.

Establishing an irradiation parameter in consideration of nonuniformity of the positions or sizes of the pulse-irradiated marks 1 is an effective way in terms of the performance of the marking unit. By referring to FIG. 2, the distance d2 between the centers of continuous pulse-irradiated marks 1 may be twice the diameter d1 of the pulse-irradiated marks 1 or more, for example. In this case, the pulse-irradiated marks 1 will not overlap each other even if nonuniformity on a scale of about half the diameter d1 is generated in the positions or diameters of the pulse-irradiated marks 1.

The present inventors have confirmed by experiment that the identifier 101 to be engraved on the SiC wafer 100 is provided with sufficient visibility if the energy of one pulse (pulse energy) is 5 μJ or higher. The present inventors have also confirmed that the pulse energy of higher than 10 μJ generates crystal damage of the SiC wafer 100, or increases particles due to excessively great depth of the resultant pulse-irradiated marks 1. So, in order to achieve both the provision of visibility and suppression of particles, the output power and the Q-switch frequency are preferably determined such that the pulse energy falls within a range of from 5 to 10 μJ.

Referring to the depth of the pulse-irradiated marks 1, it has been confirmed that the identifier 101 to be engraved on the SiC wafer 100 is provided with sufficient visibility if the depth is 0.1 μm or more. It has also been confirmed that increase of particles becomes noticeable if the depth of the pulse-irradiated marks 1 is 0.7 μm or more. So, in order to achieve both the provision of visibility and suppression of particles, the output power and the Q-switch frequency are preferably determined such that the depth of the pulse-irradiated marks 1 falls within a range of from 0.1 to 0.7 μm.

While the invention has been shown and described in detail, the foregoing description is in all aspects illustrative and not restrictive. It is therefore understood that numerous modifications and variations can be devised without departing from the scope of the invention.

What is claimed is:

1. A method of marking an SiC semiconductor wafer, comprising the steps of:
(a) preparing an SiC semiconductor wafer; and
(b) applying a laser from a laser head to said SiC semiconductor wafer while causing said laser head to move relative to said SiC semiconductor wafer, thereby engraving a predetermined pattern on a surface of said SiC semiconductor wafer, the predetermined pattern having irradiation marks as a result of irradiation with said laser, wherein
said laser is a pulsed laser of a wavelength four times that of a YAG laser, and
in said step (b), said laser head moves at a speed that prevents overlap between irradiation marks by continuous pulses of said pulsed laser, and in an orbit that prevents one of said irradiation marks previously formed from being irradiated with said pulsed-laser again.

2. The method according to claim 1, wherein
said predetermined pattern is an aggregate of dots that do not overlap each other, and
said step (b) includes the steps of:
(b-1) rendering each of said dots with a plurality of said irradiation marks not overlapping each other; and
(b-2) rendering said predetermined pattern with a plurality of dots by repeating said step (b-1).

3. The method according to claim 1, further comprising the step of:
setting a distance between the centers of continuous ones of said irradiation marks by controlling at least either a speed at which said laser head moves or the Q-switch frequency of said pulsed laser.

4. The method according to claim 3, wherein said distance between the centers of said continuous irradiation marks is twice the diameter of the irradiation marks or more.

5. The method according to claim 1, wherein the energy of one pulse of said pulsed laser is from 5 to 10 μJ.

6. The method according to claim 1, wherein the depth of said irradiation marks is from 0.1 to 0.7 μm.

7. An SiC semiconductor wafer with a surface engraved with a predetermined pattern having irradiation marks as a result of irradiation with a laser, wherein
said predetermined pattern is an aggregate of said irradiation marks not overlapping each other, said irradiation marks having a depth of from 0.1 to 0.7 μm.

8. The SiC semiconductor wafer according to claim 7, wherein
said predetermined pattern is an aggregate of dots that do not overlap each other, and
said dots are each an aggregate of said irradiation marks.

9. The SiC semiconductor wafer according to claim 7, wherein a distance between the centers of adjacent ones of said irradiation marks is twice the diameter of the irradiation marks or more.
